(19) United States
(12) Patent Application Publication
(10) Pub. No.: US 2006/0123285 A1
(43) Pub. Date: Jun. 8, 2006

(54) Dynamic threshold scaling in a communication system

(76) Inventors: Daniel F. De Araujo, Tucson, AZ (US); Paul M. Richards, Tucson, AZ (US); Brian A. Rinaldi, Tucson, AZ (US); Todd C. Sorenson, Tucson, AZ (US)

Correspondence Address: QUARLES & BRADY STREICH LANG LLP, 1 SOUTH CHURCH AVENUE, SUITE 1700, TUCSON, AZ, 85701, US

(21) Appl. No.: 10/989,562

(22) Filed: Nov. 16, 2004

(51) Int. Cl. G11C 29/00

(52) U.S. Cl. 714/721

(57) ABSTRACT

A computer system including an error recovery system establishes error threshold inversely proportional to the number of a like kind of system resources, such as host adapters. When a host adapter is initialized or deactivated, a software subcomponent of a processing device calculates a new threshold number and writes it to a memory location associated with each host adapter. When a number of errors exceeds the threshold number, the host adapter is reset, quiesced for repair, or fenced for replacement.

### BACKGROUND OF THE INVENTION

1. Field of the Invention

This invention is related in general to the field of data storage systems. In particular, the invention consists of a system for dynamically scaling error thresholds in a data communication fabric.

2. Description of the Prior Art

In FIG. 1, a computer storage system 10 includes host servers (“hosts”) 12, data processing servers 14, a data storage system 16 including a plurality of data storage devices such as redundant arrays of inexpensive/independent disks (“RAIDs”), and a data communication system 18. Requests for information traditionally originate with the hosts 12, are transmitted by the communication system 18, and are processed by the data processing servers 14. The data processing servers retrieve data from the data storage devices 16 and transmit the data back to the hosts 12 through the communication system. Similarly, the hosts 12 may write data the to the data storage devices 16.

The communication system 18 may be a communication bus, a point-to-point network, or other communication scheme. FIG. 2 illustrates a communication fabric 20 including system resources such as a symmetrical multi-processor (“SMP complex”) 22, a fabric controller 24, and a host adapter 26. The SMP complex 22 is a component of the data processing server 14 (FIG. 1) and the host adapter 26 is the interface for the host servers 12 (FIG. 1). Various error conditions may occur within any of these components. These error conditions may be critical, i.e., preventing the device from functioning, or may be transitory in nature. If a critical error occurs, the failed device must be re-initialized or replaced. However, transitory errors may be addressed according to the severity and frequency of the error.

Some errors result from faulty cables, power transients, or defective components. Some of these types of errors can be tolerated and accommodated by the communication fabric 20 as spurious events. However, a large number of non-critical errors may indicate impending component failure or that a component is in an unstable state requiring re-initialization. Counters may be used to track these non-critical errors. When a counter exceeds a pre-determined threshold, corrective action may be taken by resetting a device, quiescing a device so that it may be repaired, or fencing a device so that it may be taken offline for replacement.

Typically, a system is configured with a default set of thresholds for error recovery, regardless of the number of each type of system resource. However, a one-size-fits-all approach often leads to inefficient use of system resources as use of system resources for error recovery may occur too early or too late.

In U.S. Pat. No. 5,331,476, Fry et al. disclose a data storage apparatus incorporating an error recovery system that is dynamically controlled to perform knowledge-based error recovery. However, the Fry invention does not take into account the number of available resources when dynamically performing error recovery. This may result in all resources engaging in error recovery while leaving no resources available for the performance of data transfer. Accordingly, it is desirable to have a system for scaling error thresholds in relation to the number of corresponding system resources.

### SUMMARY OF THE INVENTION

The invention disclosed herein utilizes a system of increasing or decreasing the error threshold values of all like system resource devices based on the total number of these devices. When a few devices are available, taking even a single device off-line can severely limit the bandwidth of the communication system. As such, a device should only be taken off-line when the error condition is serious or occurs with a high degree of frequency. Conversely, when a large number of devices are available, taking one or more devices off-line may have a negligible impact on system throughput. Accordingly, threshold values are set inversely proportional to the number of available devices. When the number of devices is relatively large, the error threshold values are set low and when the number of devices is relatively low, the error threshold values are set high.

Various other purposes and advantages of the invention will become clear from its description in the specification that follows and from the novel features particularly pointed out in the appended claims. Therefore, to the accomplishment of the objectives described above, this invention comprises the features hereinafter illustrated in the drawings, fully described in the detailed description of the preferred embodiments and particularly pointed out in the claims. However, such drawings and description disclose just a few of the various ways in which the invention may be practiced.

### BRIEF DESCRIPTION OF THE DRAWINGS

FIG. 1 is a block diagram illustrating a computer storage system including host servers, data processing servers, data storage devices, and a data communication system.

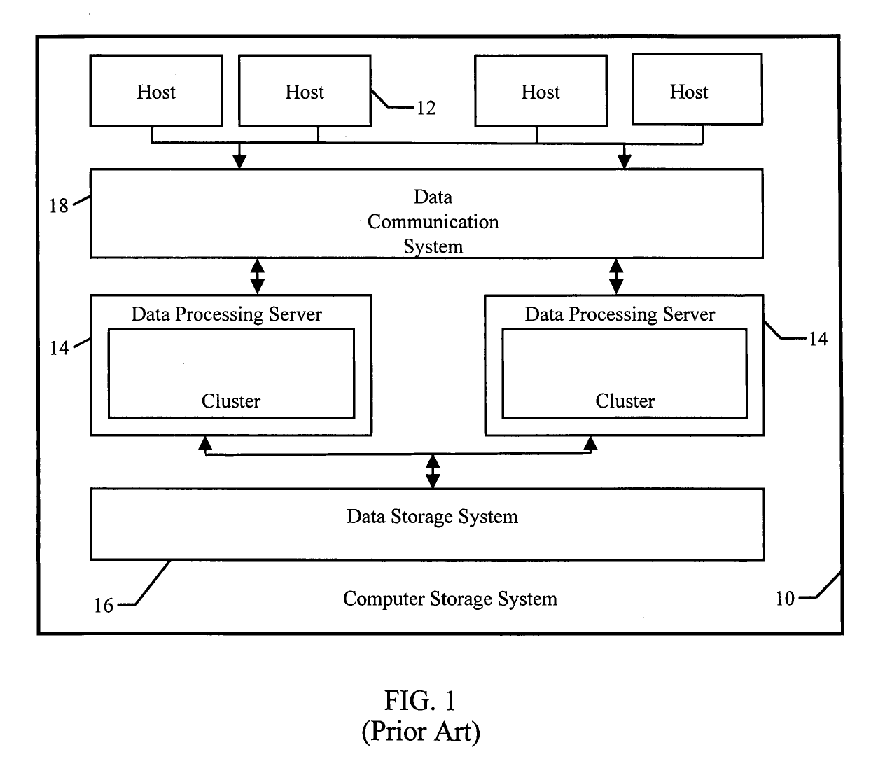

FIG. 2 is a block diagram illustrating a communication fabric including a processing device, a fabric controller, and a host adapter.

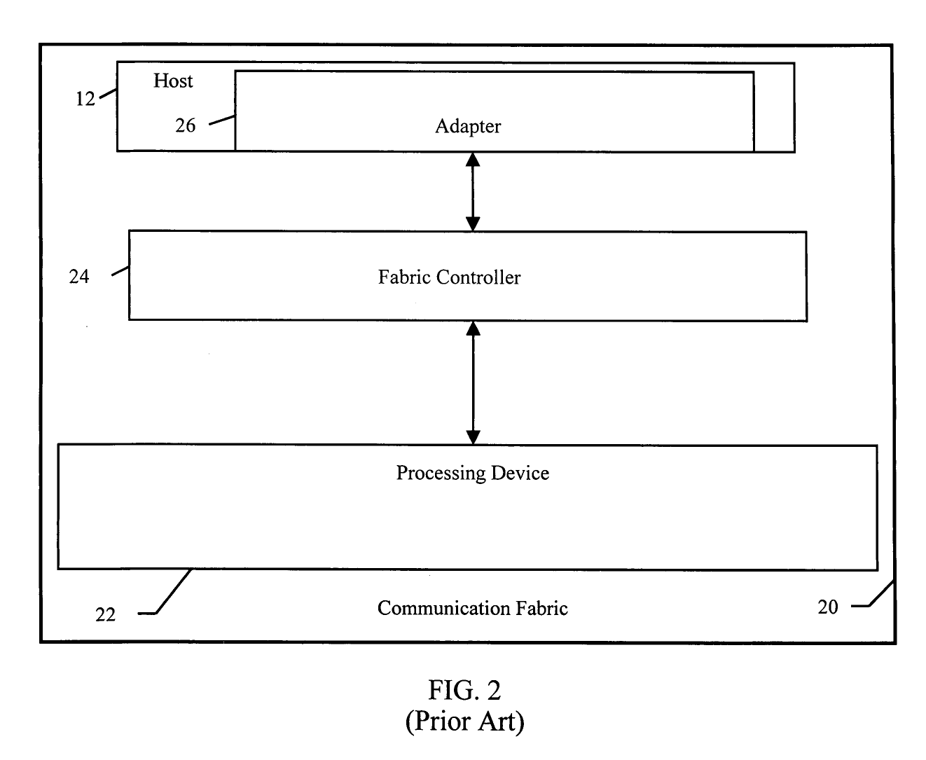

FIG. 3 is a block diagram illustrating a communication fabric, according to the invention, including error counters and error thresholds.

FIG. 4 is a flow chart illustrating a dynamic threshold scaling algorithm.

### DESCRIPTION OF THE PREFERRED EMBODIMENTS

This invention is based on the idea of using a dynamically scaled error threshold to regulate error recovery actions within a communication fabric of a computer storage system. The invention disclosed herein may be implemented as a method, apparatus or article of manufacture using standard programming or engineering techniques to produce software, firmware, hardware, or any combination thereof. The term “article of manufacture” as used herein refers to code or logic implemented in hardware or computer readable media such as optical storage devices, and volatile or non-volatile memory devices. Such hardware may include, but is not limited to, field programmable gate arrays (“FPGAs”), application-specific integrated circuits (“ASICs”), complex programmable logic devices (“CPLDs”), programmable logic arrays (“PLAs”), microprocessors, or other similar processing devices.

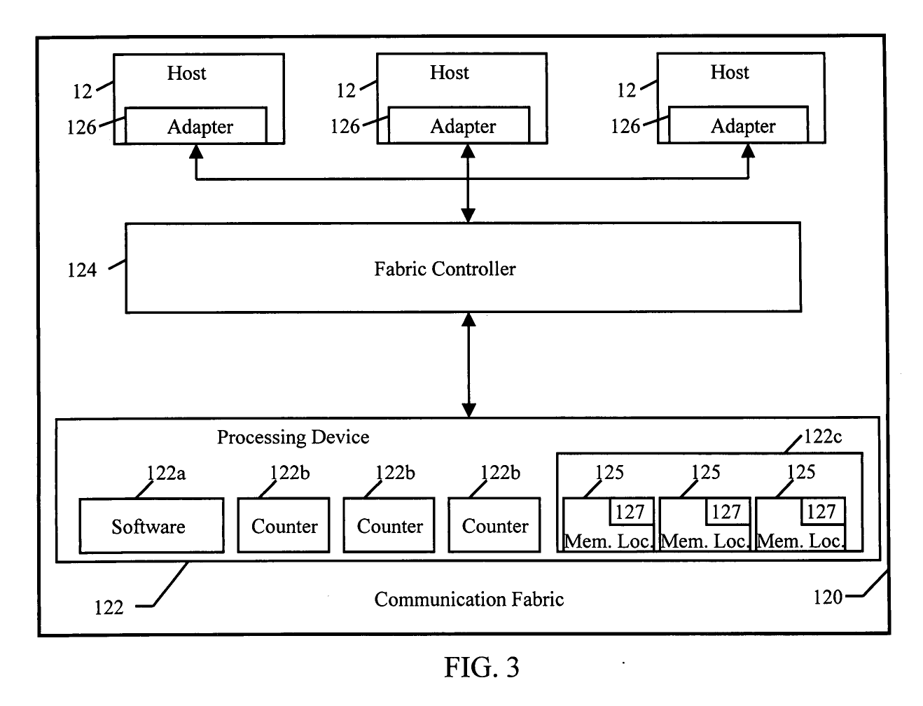

Referring to figures, wherein like parts are designated with the same reference numerals and symbols, FIG. 3 is a block diagram illustrating a communication fabric 120 including a processing device 122, a fabric controller 124, and a plurality of host adapters 126. The processing device 122 includes a software subcomponent 122a and a plurality of error counters 122b corresponding to the plurality of host adapters 126. Additionally, the processing device 122 includes a memory device 122c with a plurality of memory locations 125, each of the memory locations corresponding to one of the host adapters 126.

Error thresholds 127 are written by the software subcomponent 122a to each of the memory locations 125. The fabric controller 124 connects the processing device 122 to the host adapter 126 and the host adapter connects the communication fabric 120 to a host server (“host”). The processing device 122 may be a data processing server or a symmetric multi-processor (“SMP”) complex. The invention regulates error recovery actions to remedy these error conditions based on dynamically scaled error thresholds.

In this embodiment of the invention, five disparate error conditions may exist: (1) component timeout, (2) adapter warmstart timeout, (3) fabric interrupt, (4) adapter failure, and (5) adapter interrupt. A component timeout indicates that a fabric component has failed to provide an acknowledgement. An adapter interrupt indicates that the adapter has detected a failure but has not failed internally. A fabric interrupt indicates that a bus protocol violation has occurred.

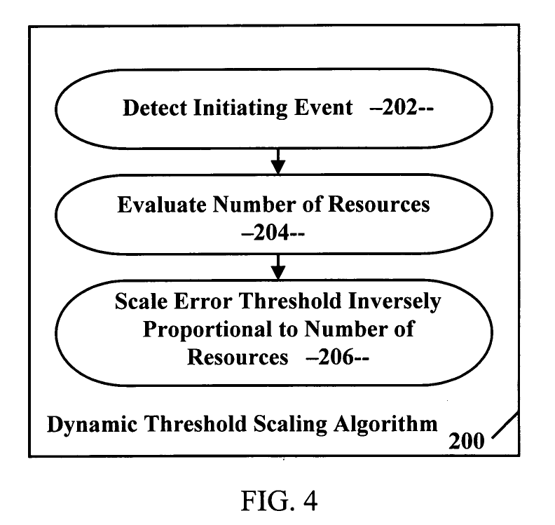

A dynamic threshold scaling algorithm 200 is illustrated by the flow chart of FIG. 4. In step 202, an initiating event is detected by the software subcomponent 122a. An initiating event may be the activation or deactivation of a host adapter 126. In step 204, the software subcomponent 122a evaluates the number of total available resources of a like kind.

In step 206, the error threshold is dynamically adjusted in inverse proportion to the number of available resources. If the number of resources increased due to the activation of a host adapter 126, the error threshold is reduced. If the number of resources decreased due to the deactivation of a host adapter 126, the error threshold is increased.

Those skilled in the art of making error recovery systems may develop other embodiments of the present invention. However, the terms and expressions which have been employed in the foregoing specification are used therein as terms of description and not of limitation, and there is no intention in the use of such terms and expressions of excluding equivalents of the features shown and described or portions thereof, it being recognized that the scope of the invention is defined and limited only by the claims which follow.

I claim:

1. An error recovery system, comprising:
a plurality of system resources;
a processing device including a memory device, the memory device including a plurality of memory locations, and each of said plurality of memory locations corresponding to one of said plurality of system resources; and
a communication channel connecting the plurality of system resources to the processing device;
wherein the processing device further includes a software subcomponent for detecting the plurality of system resources, calculating a first number representative of the plurality of system resources, calculating an error threshold inversely proportional to the first number, and writing the error threshold to each of the plurality of memory locations.

2. The error recovery system of claim 1, wherein the processing device includes a symmetric multi-processor (“SMP”) complex.

3. The error recovery system of claim 1, wherein the plurality of system resources includes a plurality of host adapters.

4. The error recovery system of claim 1, wherein the software subcomponent is adapted to detect an error condition associated with a first one of the plurality of system resources and to increment a value within an error counter corresponding to the first one of the plurality of system resources.

5. The error recovery system of claim 4, wherein, if the value exceeds the error threshold corresponding to the first one of the plurality of system resources, the first one of the plurality of system resources is reset.

6. The error recovery system of claim 4, wherein, if the value exceeds the error threshold corresponding to the first one of the plurality of system resources, the first one of the plurality of system resources is fenced.

7. The error recovery system of claim 6, wherein the first one of the plurality of system resources is quiesced.

8. The error recovery system of claim 3, wherein the software subcomponent calculates the error threshold when one of the plurality of host adapters is initialized.

9. The error recovery system of claim 3, wherein the software subcomponent calculates the error threshold when one of the plurality of host adapters is deactivated.

10. A method of error recovery, comprising the steps of:
detecting a plurality of system resources;
calculating a first number representative of the plurality of system resources;
calculating an error threshold inversely proportional to the first number; and
writing the error threshold to each of the plurality of memory locations.

11. The method of claim 10, further comprising the steps of:
detecting an error condition associated with a first one of the plurality of system resources; and
incrementing a value within an error counter corresponding to the first one of the plurality of system resources.

12. The method of claim 11, further comprising the step of, if the value exceeds the error threshold corresponding to the first one of the plurality of system resources, resetting the first one of the plurality of system resources.

13. The method of claim 11, further comprising the step of, if the value exceeds the error threshold corresponding to the first one of the plurality of system resources, quiescing the first one of the plurality of system resources.

14. The method of claim 11, further comprising the step of, if the value exceeds the error threshold corresponding to the first one of the plurality of system resources, fencing the first one of the plurality of system resources.

15. The method of claim 10, wherein the step of detecting a plurality of system resources occurs when one of the plurality of system resources is initialized.

16. The method of claim 10, wherein the step of detecting a plurality of system resources occurs when one of the plurality of system resources is deactivated.

17. An article of manufacture including a data storage medium, said data storage medium including a set of machine-readable instructions that are executable by a processing device to implement an algorithm, said algorithm comprising the steps of:
detecting a plurality of system resources;
calculating a first number representative of the plurality of system resources;
calculating an error threshold inversely proportional to the first number; and
writing the error threshold to each of the plurality of memory locations.

18. The article of manufacture of claim 17, further comprising the steps of:
detecting an error condition associated with a first one of the plurality of system resources; and
incrementing a value within an error counter corresponding to the first one of the plurality of system resources.

19. A method of providing a service for managing a support system, comprising integrating computer-readable code into a computing system, wherein the computer-readable code in combination with the computing system is capable of performing the following steps:
detecting a plurality of system resources;
calculating a first number representative of the plurality of system resources;
calculating an error threshold inversely proportional to the first number; and
writing the error threshold to each of the plurality of memory locations.

20. The method of claim 19, further comprising the steps of:
detecting an error condition associated with a first one of the plurality of system resources; and
incrementing a value within an error counter corresponding to the first one of the plurality of system resources.
